(19) United States
(12) Patent Application Publication
(10) Pub. No.: US 2024/0164069 A1
(43) Pub. Date: May 16, 2024

(54) CERAMIC SUBSTRATE STRUCTURE AND POWER MODULE HAVING THE SAME

(71) Applicant: INDUSTRIAL TECHNOLOGY RESEARCH INSTITUTE, Hsinchu (TW)

(72) Inventors: Yue-Zhen HUANG, Yilan County (TW); Meng-Chi HUANG, Taoyuan City (TW); Tune-Hune KAO, Hsinchu City (TW); Min-Chieh CHOU, Taipei City (TW); Jie-Chi CHEN, Taoyuan City (TW)

(73) Assignee: INDUSTRIAL TECHNOLOGY RESEARCH INSTITUTE, Hsinchu (TW)

(21) Appl. No.: 18/086,062

(22) Filed: Dec. 21, 2022

(30) Foreign Application Priority Data
Nov. 16, 2022 (TW) 111143728

(51) Int. Cl. H05K 7/20; H05K 1/03; H05K 1/18

(52) U.S. Cl. CPC H05K 7/209; H05K 1/0306; H05K 1/181; H05K 2201/10166

(57) ABSTRACT

A ceramic substrate structure includes a ceramic board, a first conductive layer, a second conductive layer and a heat dissipation layer. The ceramic board has a first surface and a second surface opposite to each other. Each of the first surface and the second surface is a single surface extending continuously. The first conductive layer is mounted on the first surface of the ceramic board. The second conductive layer is mounted on the first surface of the ceramic board. The second conductive layer is adjacent to the first conductive layer and have different thicknesses. The heat dissipation layer is mounted on the second surface of the ceramic board. The heat dissipation layer includes a first heat dissipation portion corresponding to the first conductive layer and a second heat dissipation portion corresponding to the second conductive layer, and the second heat dissipation portion has a patterned region.

### CROSS-REFERENCE TO RELATED APPLICATIONS

This application claims priority under 35 U.S.C. § 119(a) on Patent Application No(s). 111143728 filed in Taiwan, R.O.C. on Nov. 16, 2022, the entire contents of which are hereby incorporated by reference.

### TECHNICAL FIELD

This present disclosure relates to a ceramic substrate structure and a power module.

### BACKGROUND

At present, power modules that include ceramic materials such as aluminum oxide, silicon nitride, aluminum nitride or zirconia toughened alumina (ZTA) are widely used in automotive industry. A conventional power module generally includes an insulated-gate bipolar transistor (IGBT) module in which the ceramic materials are used to fabricate a substrate for carrying IGBT power device due to their high thermal conductivity, high electrical insulation and low coefficients of thermal expansion.

The power density of a power module can be defined as the maximum power that can be output by the power module divided by weight, volume or area of the whole power module. With the trend towards high power density, there is an increasing demand for a power module featuring light weight, small size and dense configuration. However, the development of power module with high power density is restricted by heat dissipation problems, so that a solution for meeting the requirements of improved heat dissipation efficiency as well as miniaturization of power module is an issue to be solved in this field.

A ceramic substrate structure fabricated by depositing a metal layer onto a ceramic board is a solution to the heat dissipation problems. As to a conventional configuration, the high power devices and the gate drivers are mounted on different ceramic boards, respectively.

### SUMMARY

According to one embodiment of the present disclosure, a ceramic substrate structure includes a ceramic board, a first conductive layer, a second conductive layer and a heat dissipation layer. The ceramic board has a first surface and a second surface opposite to each other. Each of the first surface and the second surface is a single surface extending continuously. The first conductive layer is mounted on the first surface of the ceramic board. The second conductive layer is mounted on the first surface of the ceramic board. The second conductive layer is adjacent to the first conductive layer, and the first conductive layer and the second conductive layer have different thicknesses. The heat dissipation layer is mounted on the second surface of the ceramic board. The heat dissipation layer includes a first heat dissipation portion and a second heat dissipation portion. The first heat dissipation portion corresponds to the first conductive layer, the second heat dissipation portion corresponds to the second conductive layer, and the second heat dissipation portion has a patterned region.

According to another embodiment of the present disclosure, a power module includes a ceramic substrate structure, a power semiconductor device and a gate driver. The ceramic substrate structure includes a ceramic board, a first conductive layer, a second conductive layer and a heat dissipation layer. The ceramic board has a first surface and a second surface opposite to each other. Each of the first surface and the second surface is a single surface extending continuously. The first conductive layer is mounted on the first surface of the ceramic board. The second conductive layer is mounted on the first surface of the ceramic board. The second conductive layer is adjacent to the first conductive layer, and the first conductive layer and the second conductive layer have different thicknesses. The heat dissipation layer is mounted on the second surface of the ceramic board. The power semiconductor device is mounted on the first conductive layer. The gate driver is mounted on the second conductive layer. The heat dissipation layer includes a first heat dissipation portion and a second heat dissipation portion. The first heat dissipation portion corresponds to the first conductive layer, the second heat dissipation portion corresponds to the second conductive layer, and the second heat dissipation portion has a patterned region.

### BRIEF DESCRIPTION OF THE DRAWINGS

FIG. 1 is a perspective view of a ceramic substrate structure according to one embodiment of the present disclosure;

FIG. 2 is another perspective view of the ceramic substrate structure in FIG. 1;

FIG. 3 is a bottom view of the ceramic substrate structure in FIG. 1;

FIG. 4 is a cross-sectional view of the ceramic substrate structure in FIG. 1;

FIG. 5 is a perspective view of a ceramic substrate structure according to another embodiment of the present disclosure;

FIG. 6 is a perspective view of a ceramic substrate structure according to still another embodiment of the present disclosure;

FIG. 7 through FIG. 10 are schematic views showing fabrication of the ceramic substrate structure in FIG. 1;

FIG. 11 is a perspective view of a ceramic substrate structure according to yet another embodiment of the present disclosure;

FIG. 12 is a schematic view of a power module according to one embodiment of the present disclosure; and

FIG. 13 is a schematic view of a power module according to another embodiment of the present disclosure.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present disclosure. The following embodiments further illustrate various aspects of the present disclosure, but are not meant to limit the scope of the present disclosure.

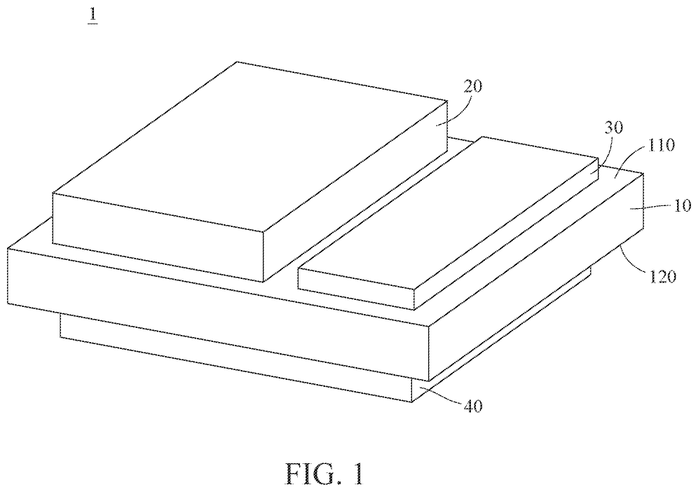

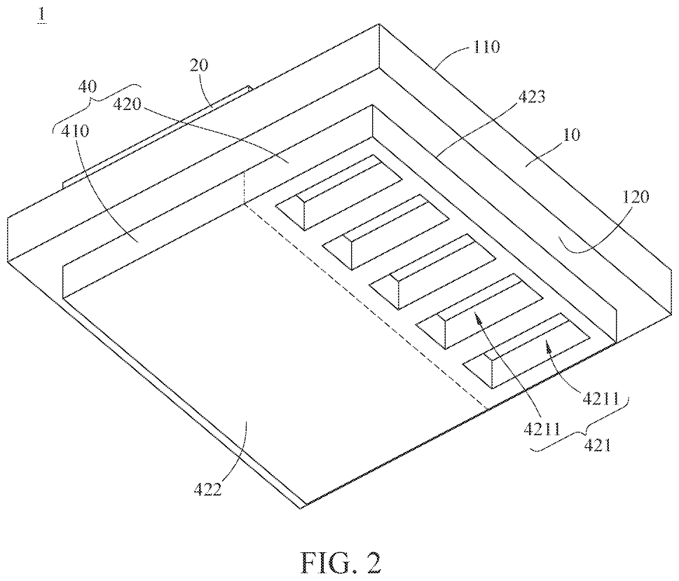

Please refer to FIG. 1 and FIG. 2. FIG. 1 is a perspective view of a ceramic substrate structure according to one embodiment of the present disclosure, and FIG. 2 is another perspective view of the ceramic substrate structure in FIG. 1. In this embodiment, a ceramic substrate structure 1 may include a ceramic board 10, a first conductive layer 20, a second conductive layer 30 and a heat dissipation layer 40.

The ceramic board 10 is, for example but not limited to, an aluminum oxide board, a silicon nitride board or a ZTA board. The ceramic board 10 has a top surface 110 and a bottom surface 120 opposite to each other. In this embodiment, the ceramic board 10 is a single ceramic board, and thus each of the top surface 110 and the bottom surface 120 is a single surface extending continuously. More specifically, each of the top surface 110 and the bottom surface 120 is a single and flat surface.

The first conductive layer 20 and the second conductive layer 30 are mounted on the top surface 110 of the ceramic board 10 and adjacent to each other. The first conductive layer 20 and the second conductive layer 30 may be made of metal material. For example, each of the first conductive layer 20 and the second conductive layer 30 may be a copper layer formed on the top surface 110 of the ceramic board 10. The first conductive layer 20 and the second conductive layer 30 have different thicknesses. More specifically, the first conductive layer 20 has greater thickness than the second conductive layer 30. In one implementation, a thickness of the first conductive layer 20 may be from 300 micrometers (μm) to 1000 μm, and a thickness of the second conductive layer 30 may be from 30 μm to 100 μm. The thick first conductive layer 20 can be configured to one or more carry power semiconductor devices, the thin second conductive layer 30 can be configured to carry a gate driver, and the details will be further described hereafter. Moreover, the thicknesses of the first conductive layer 20 and the second conductive layer 30 mentioned above refer to an average thickness of respective conductive layer.

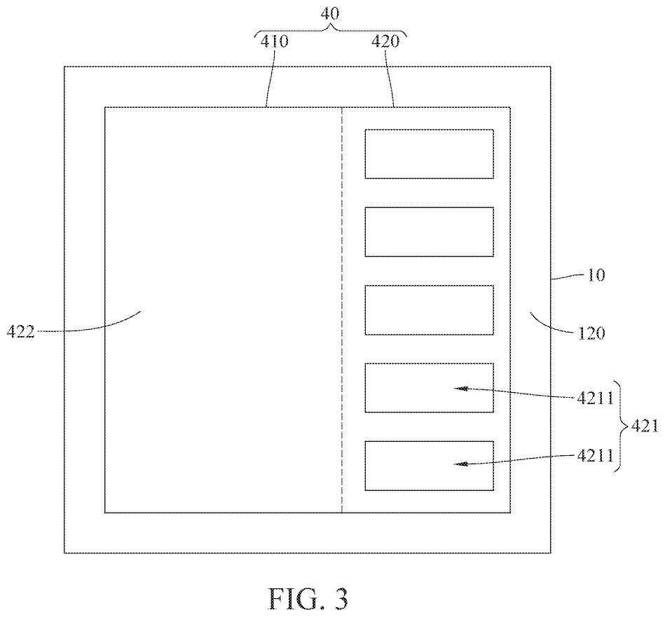

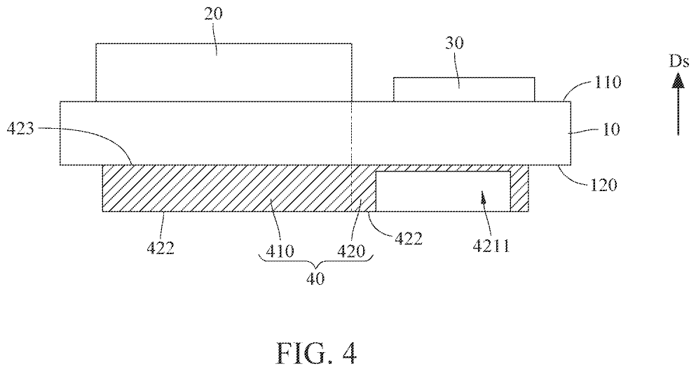

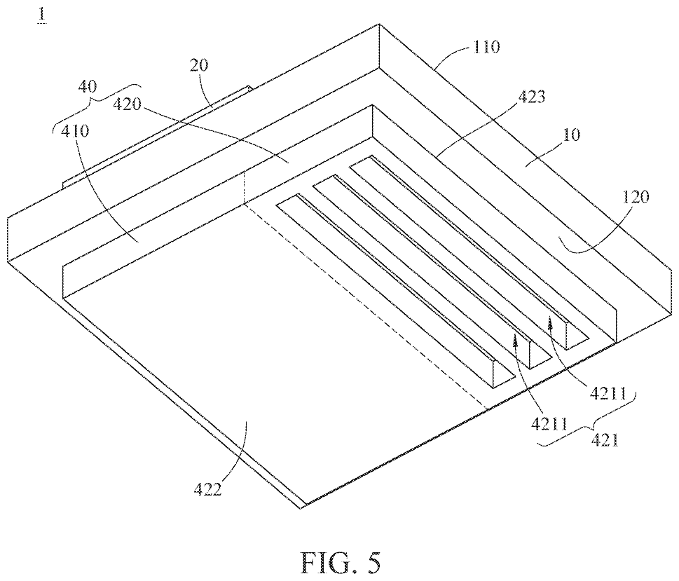

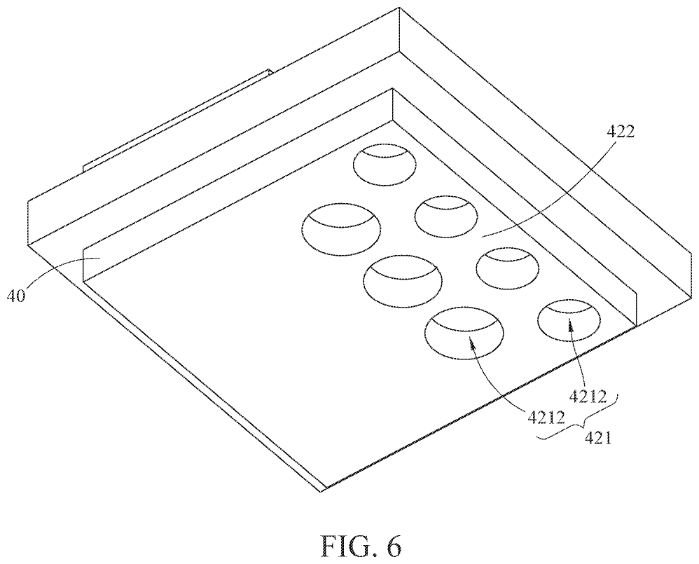

The heat dissipation layer 40 is mounted on the bottom surface 120 of the ceramic board 10. FIG. 3 is a bottom view of the ceramic substrate structure in FIG. 1, and FIG. 4 is a cross-sectional view of the ceramic substrate structure in FIG. 1. The heat dissipation layer 40 may be made of metal material. For example, the heat dissipation layer 40 may be formed on the bottom surface 120 of the ceramic board 10. The heat dissipation layer 40 may include a first heat dissipation portion 410 and a second heat dissipation portion 420. The first heat dissipation portion 410 corresponds to the first conductive layer 20, and the second heat dissipation portion 420 corresponds to the second conductive layer 30. More specifically, the first heat dissipation portion 410 may be connected with the second heat dissipation portion 420, and the second heat dissipation portion 420 of the heat dissipation layer 40 may have a patterned region 421. As shown in FIG. 3 and FIG. 4, the patterned region 421 is one or more blind holes, one or more trenches or one or more through holes, but the present disclosure is not limited to. As shown in FIG. 2 and FIG. 3, the patterned region 421 include one or more trenches 4211 extending from a bottom surface 422 of the second heat dissipation portion 420 of the heat dissipation layer 40 toward the ceramic board 10. In some embodiments, the trenches of the patterned region may extend in a direction different from the trenches 4211 in FIG. 2, as the trenches 4211 in FIG. 5 which depicts a perspective view of a ceramic substrate structure according to another embodiment of the present disclosure. In some embodiments, the trenches of the patterned region may extend from the bottom surface of the heat dissipation layer to the bottom surface of the ceramic board so as to penetrate the heat dissipation layer. In some embodiments, the patterned region 421 may be one or more blind holes 4212 each having an opening at the bottom surface 422 of the heat dissipation layer 40, as shown in FIG. 6 which depicts a perspective view of a ceramic substrate structure according to still another embodiment of the present disclosure. In some embodiments, the patterned region may be one or more through holes extending from the bottom surface of the heat dissipation layer to the bottom surface of the ceramic board.

As shown in FIG. 4, the ceramic board 10 and the second conductive layer 30 are arranged along a first direction Ds, and the patterned region 421 correspond to the second conductive layer 30 in the first direction Ds. That is, a projection of the trenches 4211 of the patterned region 421 onto the top surface 110 of the ceramic board 10 overlaps the second conductive layer 30.

As shown in FIG. 3 and FIG. 4, the second heat dissipation portion 420 has approximate volume to the second conductive layer 30. Specifically, a volume ratio of the first heat dissipation portion 410 to the first conductive layer 20 is from 0.5 to 2, and a volume ratio of the second heat dissipation portion 420 to the second conductive layer 30 is from 0.5 to 2. In another embodiment, the volume ratio of the first heat dissipation portion to the first conductive layer is from 0.8 to 1.2, and the volume ratio of the second conductive layer to the second conductive layer is from 0.8 to 1.2. The volume of the first conductive layer 20, the second conductive layer 30, the first heat dissipation portion 410 or the second heat dissipation portion 420 refers to the volume of a solid part of said layer. The volume of the second heat dissipation portion 420 does not take the space occupied by the blind holes, trenches or through holes of the patterned region 421 into consideration.

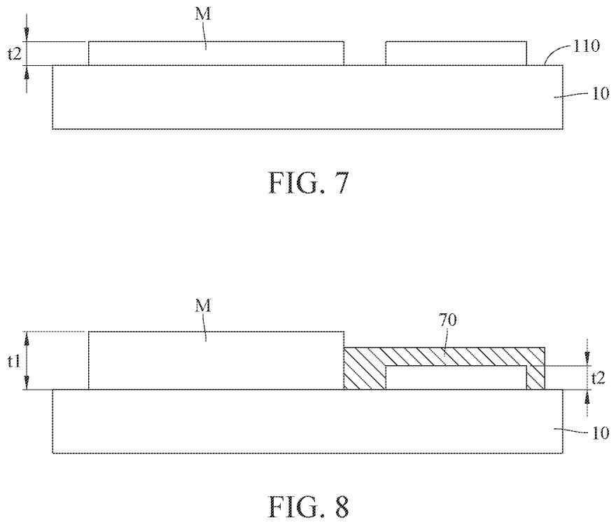

The fabrication of the ceramic substrate structure 1 is described hereafter. FIG. 7 through FIG. 10 are schematic views showing fabrication of the ceramic substrate structure in FIG. 1. As shown in FIG. 7, a patterned metal layer M is a copper layer with thickness t2 formed on the top surface 110 of the ceramic board 10, and the formation of the patterned metal layer M is performed by, for example, electroplating, sputtering or electroless plating. The patterns on the patterned metal layer M can be used for wiring layout of semiconductor components.

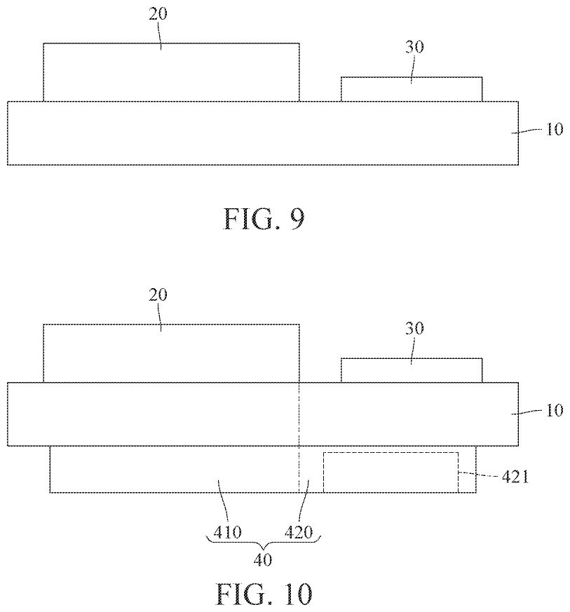

As shown in FIG. 8 and FIG. 9, part of the patterned metal layer M is covered by an insulating tape 70, and the uncovered part of the patterned metal layer M is thickened to have a thickness t1. The thickening of the patterned metal layer is performed, for example but not limited to, by electroplating, sputtering or electroless plating. After the thickening of the patterned metal layer is completed, the insulating tape 70 is removed, and the thick portion of the patterned metal layer is taken as the first conductive layer 20 in FIG. 1. The thin portion of the patterned metal layer which is not covered by the insulating tape 70 previously is taken as the second conductive layer 30 in FIG. 1.

As shown in FIG. 10, a metal layer is formed under the bottom surface 120 of the ceramic board 10, and the formation of the metal layer is performed by, for example, electroplating, sputtering or electroless plating. The metal layer is taken as the heat dissipation layer 40 in FIG. 1 which can be divided into the first heat dissipation portion 410 corresponding to the first conductive layer 20 and the second heat dissipation portion 420 corresponding to the second conductive layer 30. Then, blind hole, trench or though hole may be formed in the second heat dissipation portion 420 to be the patterned region 421.

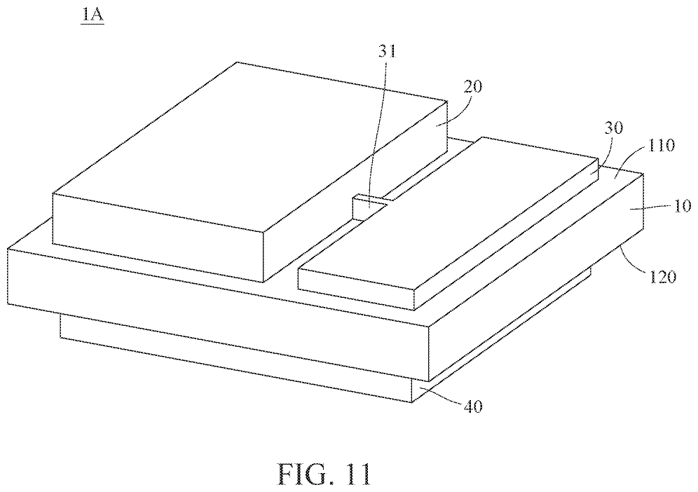

According to one embodiment of the present disclosure, the ceramic substrate structure may include a connection portion. FIG. 11 is a perspective view of a ceramic substrate structure according to yet another embodiment of the present disclosure. In this embodiment, a ceramic substrate structure 1A may include a ceramic board 10, a first conductive layer 20, a second conductive layer 30, a connection portion 31 and a heat dissipation layer 40. Any detail of the ceramic board 10, the first conductive layer 20, the second conductive layer 30 and the heat dissipation layer 40 can be referred to FIG. 1 through FIG. 4 as well as the aforementioned description related to these elements, and thus will be omitted hereafter.

The connection portion 31 is mounted on the top surface 110 of the ceramic board 10. The connection portion 31 may be made of metal material. For example, the connection portion 31 may be a copper layer formed on the top surface 110 of the ceramic board 10. The first conductive layer 20 may be electrically connected with the second conductive layer 30 through the connection portion 31. More specifically, opposite ends of the connection portion 31 on the ceramic board 10 are connected with the first conductive layer 20 and the second conductive layer 30, respectively, in order to enable the electrical connection.

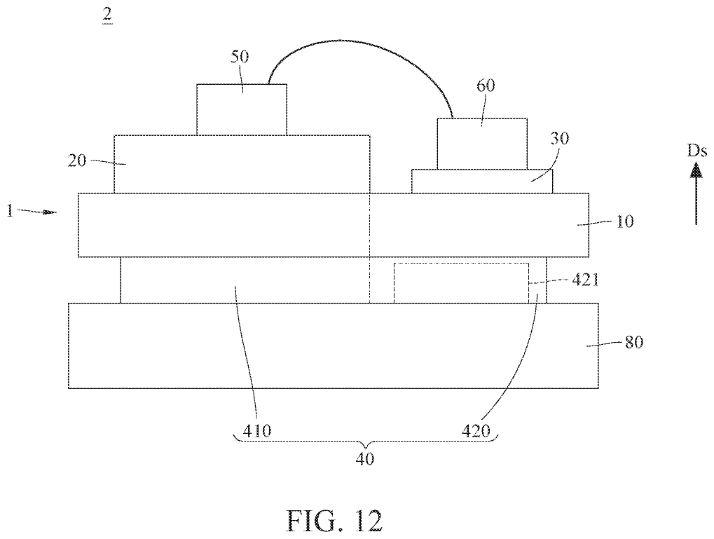

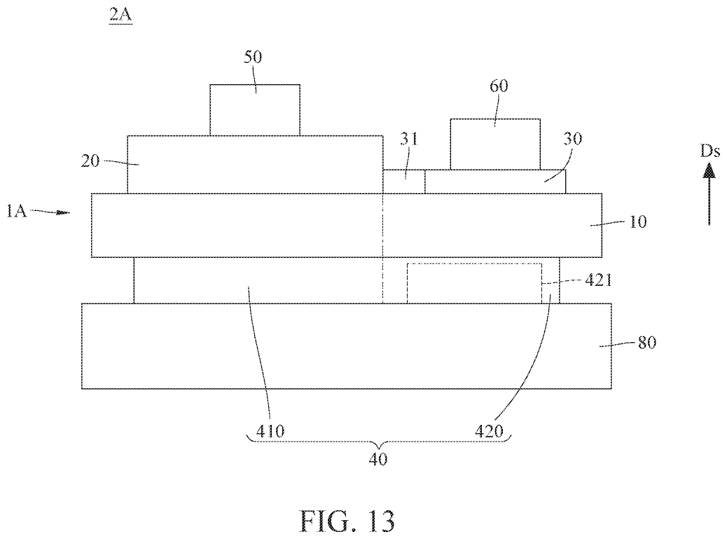

The ceramic substrate structure may be applied to power module. FIG. 12 is a schematic view of a power module according to one embodiment of the present disclosure. In this embodiment, a power module 2 may include the ceramic substrate structure 1, a power semiconductor device 50 and a gate driver 60. Any detail of the ceramic substrate structure 1 can be referred to FIG. 1 through FIG. 6 as well as the aforementioned description related to this element, and thus will be omitted hereafter.

The power semiconductor device 50 is, for example but not limited to, a power discrete device such as MOSFET or IGBT, and the power semiconductor device 50 is mounted on the first conductive layer 20 of the ceramic substrate structure 1. The gate driver 60 is mounted on the second conductive layer 30 of the ceramic substrate structure 1. The first heat dissipation portion 410 of the heat dissipation layer 40 corresponds to the first conductive layer 20, and the second heat dissipation portion 420 corresponds to the second conductive layer 30. The patterned region 421 of the second heat dissipation portion 420 corresponds to the second conductive layer 30 in the first direction Ds.

In addition to the power semiconductor device 50, a SiC power device, a RG resistor, a passive component and/or a temperature sensor may be further mounted on the first conductive layer 20. In addition to the gate driver 60, an additional driver, a passive components, a temperature sensors and/or an overcurrent protector may be mounted on the second conductive layer 30.

The power semiconductor device 50 is electrically connected with the gate driver 60. As shown in FIG. 12, the power semiconductor device 50 and the gate driver 60 are electrically connected with each other by wire bonding, but the present disclosure is not limited thereto. In another embodiment, the first conductive layer 20 and the second conductive layer 30 may be connected with each other by wire bonding so as to enable the electrical connection between the power semiconductor device 50 and the gate driver 60.

The ceramic board 10, the first conductive layer 20, the second conductive layer 30 and the heat dissipation layer 40 may be formed as a DBC (Direct bonding copper) substrate in the power module 2. The gate driver 60 can control the operation of the power semiconductor device 50. Furthermore, the ceramic board 10, the first conductive layer 20, the second conductive layer 30 and the heat dissipation layer 40 jointly provide a heat dissipation path allowing heat transfer from the power semiconductor device 50 and the gate driver 60 to a heat sink 80 below the heat dissipation layer 40. The heat sink 80 is, for example but not limited to, a thermal management device including fins or heat pipes.

Also, the first conductive layer 20 and the second conductive layer 30 have different thicknesses. The thick first conductive layer 20 is helpful to improve heat dissipation efficiency so as to be suitable for mounting the power semiconductor device 50. The thin second conductive layer 30 is helpful to provide high accuracy of electrode placement so as to be suitable for mounting the gate driver 60.

FIG. 13 is a schematic view of a power module according to another embodiment of the present disclosure. In this embodiment, a ceramic substrate structure 2A may include the ceramic substrate structure 1A, a power semiconductor device 50 and a gate driver 60. Any detail of the ceramic substrate structure 1A can be referred to FIG. 11 as well as the aforementioned description related to this element, and thus will be omitted hereafter.

The power semiconductor device 50 is mounted on the first conductive layer 20 of the ceramic substrate structure 1A. The gate driver 60 is mounted on the second conductive layer 30 of the ceramic substrate structure 1A. The first heat dissipation portion 410 of the heat dissipation layer 40 corresponds to the first conductive layer 20, and the second heat dissipation portion 420 corresponds to the second conductive layer 30. The patterned region 421 of the second heat dissipation portion 420 corresponds to the second conductive layer 30 in the first direction Ds. The power semiconductor device 50 is electrically connected with the gate driver 60.

As shown in FIG. 13, the power semiconductor device 50 and the gate driver 60 are electrically connected with each other via the first conductive layer 20, the connection portion 31 and the second conductive layer 30. Compared to the power semiconductor component and the gate driver, which are connected by wire bonding, in a conventional power module, the connection portion 31 on the ceramic board 10 is helpful to prevent parasitic inductance, thus enhancing the performance of the power module.

In order to allow the heat dissipation layer to transfer a large amount of heat in a short time period, the heat dissipation layer is provided with relatively great thickness. When two conductive layers are mounted on the same surface of a single ceramic board, if the heat dissipation layer is a metal layer with uniform thickness, a portion of the heat dissipation layer corresponding to the conductive layer for mounting gate driver has much greater volume than said conductive layer, even though the heat dissipation layer has approximate thickness to said conductive layer. A large-sized heat dissipation layer causes warpage of the ceramic substrate structure due to uneven distribution of thermal stress when the temperature of said conductive layer rises. In order to prevent unfavorable cases such as warpage, the heat dissipation layer 40 in the ceramic substrate structures 1 and 1A according to the present disclosure includes the patterned region 421 in the second heat dissipation portion 420 thereof. The patterned region 421 is favorable for the second heat dissipation portion 420 having approximate (very close or substantially equal) volume to the second conductive layer 30 for mounting the gate driver 60. Therefore, it is helpful to prevent warpage of the ceramic board 10 due to temperature rise of the second conductive layer 30.

According to the present disclosure, the first conductive layer for mounting power semiconductor device and the second conductive layer for mounting gate driver are mounted on the same surface of a single ceramic board. Therefore, it is helpful for compactness of the power module. Moreover, the heat dissipation layer is mounted on opposite surface of the ceramic board so as to be helpful to improve heat dissipation efficiency.

Further, the heat dissipation layer includes a second heat dissipation portion having patterned region, and the second heat dissipation portion corresponds to the thin second conductive layer. The patterned region makes is favorable for the second heat dissipation portion having approximate volume to the second conductive layer. Therefore, it is helpful to prevent warpage of the ceramic board due to temperature rise of the second conductive layer.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A ceramic substrate structure, comprising:
a ceramic board having a first surface and a second surface opposite to each other, wherein each of the first surface and the second surface is a single surface extending continuously; and
a first conductive layer mounted on the first surface of the ceramic board;
a second conductive layer mounted on the first surface of the ceramic board, wherein the second conductive layer is adjacent to the first conductive layer, and the first conductive layer and the second conductive layer have different thicknesses; and
a heat dissipation layer mounted on the second surface of the ceramic board, wherein the heat dissipation layer comprises a first heat dissipation portion and a second heat dissipation portion, the first heat dissipation portion corresponds to the first conductive layer, the second heat dissipation portion corresponds to the second conductive layer, and the second heat dissipation portion has a patterned region.

2. The ceramic substrate structure according to claim 1, wherein the first conductive layer has greater thickness than the second conductive layer.

3. The ceramic substrate structure according to claim 1, further comprising a connection portion mounted on the first surface of the ceramic board, wherein the first conductive layer is electrically connected with the second conductive layer through the connection portion.

4. The ceramic substrate structure according to claim 1, wherein the patterned region is one or more blind holes, one or more trenches or one or more through holes.

5. The ceramic substrate structure according to claim 1, wherein the ceramic board and the second conductive layer are arranged along a first direction, and the patterned region corresponds to the second conductive layer in the first direction.

6. The ceramic substrate structure according to claim 1, wherein a volume ratio of the second heat dissipation portion to the second conductive layer is from 0.5 to 2.

7. The ceramic substrate structure according to claim 6, wherein the volume ratio of the second heat dissipation portion to the second conductive layer is from 0.8 to 1.2.

8. A power module, comprising:
a ceramic substrate structure, comprising:
a ceramic board having a first surface and a second surface opposite to each other, wherein each of the first surface and the second surface is a single surface extending continuously;
a first conductive layer mounted on the first surface of the ceramic board;
a second conductive layer mounted on the first surface of the ceramic board, wherein the second conductive layer is adjacent to the first conductive layer, and the first conductive layer and the second conductive layer have different thicknesses; and
a heat dissipation layer mounted on the second surface of the ceramic board;
a power semiconductor device mounted on the first conductive layer; and
a gate driver mounted on the second conductive layer;
wherein the heat dissipation layer comprises a first heat dissipation portion and a second heat dissipation portion, the first heat dissipation portion corresponds to the first conductive layer, the second heat dissipation portion corresponds to the second conductive layer, and the second heat dissipation portion has a patterned region.

9. The power module according to claim 8, wherein the ceramic board, the second conductive layer and the gate driver are arranged along a first direction, and the patterned region corresponds to the gate driver in the first direction.

10. The power module according to claim 8, wherein the patterned region is one or more blind holes, one or more trenches or one or more through holes.

11. The power module according to claim 8, wherein the ceramic substrate structure further comprises a connection portion mounted on the first surface of the ceramic board, and the first conductive layer is electrically connected with the second conductive layer through the connection portion.

12. The power module according to claim 8, wherein a volume ratio of the second heat dissipation portion to the second conductive layer is from 0.5 to 2.

13. The power module according to claim 12, wherein the volume ratio of the second heat dissipation portion to the second conductive layer is from 0.8 to 1.2.
